(19) United States
(12) Patent Application Publication
(10) Pub. No.: US 2015/0340250 A1
(43) Pub. Date: Nov. 26, 2015

(54) WET ETCHING NOZZLE, SEMICONDUCTOR MANUFACTURING EQUIPMENT INCLUDING THE SAME, AND WET ETCHING METHOD USING THE SAME

(71) Applicant: Samsung Electronics Co., Ltd., Suwon-Si (KR)

(72) Inventors: Mong-Sup LEE, Hwaseong-si (KR); Dong-Gyun HAN, Yongin-si (KR); Jong-Hyuk PARK, Hwaseong-si (KR)

(21) Appl. No.: 14/562,010

(22) Filed: Dec. 5, 2014

(30) Foreign Application Priority Data
May 23, 2014 (KR) 10-2014-0062281

(51) Int. Cl. H01L 21/67

(52) U.S. Cl. CPC H01L 21/6708; H01L 21/67051

(57) ABSTRACT

A wet etching nozzle, semiconductor manufacturing equipment including the same, and a wet etching method using the same are provided. The wet etching nozzle includes a first supply pipe configured to supply a first solution, for etching a partial area of an etched layer, to a substrate including the etched layer; a first suction pipe configured to suck the first solution from the substrate; a second supply pipe configured to supply a second solution for cleaning the partial area of the etched layer; and a second suction pipe configured to suck the second solution from the substrate.

### CROSS-REFERENCE TO RELATED APPLICATIONS

This application is based on and claims priority from Korean Patent Application No. 10-2014-0062281, filed on May 23, 2014 in the Korean Intellectual Property Office, the disclosure of which is incorporated herein in its entirety by reference.

### BACKGROUND

1. Technical Field

The present invention relates to a wet etching nozzle, semiconductor manufacturing equipment including the same, and/or a wet etching method using the same.

2. Description of the Prior Art

Recently, for the price competitiveness of semiconductor devices, the number of products of semiconductor devices has been increased by increasing the number of semiconductor devices included per unit wafer through reduction of a design rule or increasing the size of the wafer.

As the size of the wafer for producing semiconductor devices is increased, it may be difficult to constantly maintain the dispersion of thin films deposited on the wafer and to constantly maintain the statistical dispersion of the etched amount when the deposited thin film is etched.

To increase the production yield of the semiconductor devices, it is important to improve the dispersion for each process and particularly to improve the dispersion of an edge portion of the wafer.

### SUMMARY

In an embodiment, a wet etching nozzle locally uses a thin film having non-uniform dispersion in wet etching.

In an embodiment, semiconductor manufacturing equipment which includes the wet etching nozzle is provided.

In an embodiment, a wet etching method locally performs wet etching of a thin film using the wet etching nozzle of the semiconductor manufacturing equipment.

In one aspect of the present invention, there is provided a wet etching nozzle comprising a first supply pipe configured to supply a first solution to a substrate including an etched layer, the first solution for etching a partial area of the etched layer, a first suction pipe configured to suck the first solution from the substrate, a second supply pipe configured to supply a second solution for cleaning the partial area of the etched layer, and a second suction pipe configured to suck the second solution from the substrate.

The wet etching nozzle may further comprise a third supply pipe configured to supply a third solution for cleaning the etched layer, a third suction pipe configured to suck the third solution from the substrate, and a fourth supply pipe configured to supply a gas for drying the etched layer.

The first supply pipe, the first suction pipe, the second supply pipe, and the second suction pipe are in the form of circles, respectively, and the first supply pipe, the first suction pipe, the second supply pipe, and the second suction pipe are arranged in the form of concentric circles.

The first supply pipe, the first suction pipe, the second supply pipe, and the second suction pipe are successively arranged in a radial direction.

The first supply pipe, the first suction pipe, the second supply pipe, and the second suction pipe are successively arranged in one direction.

The wet etching nozzle may further comprise a third suction pipe arranged to correspond to the first suction pipe around the first supply pipe to suck the first solution, a third supply pipe arranged to correspond to the second supply pipe around the first supply pipe to supply the second solution, and a fourth suction pipe arranged to correspond to the second suction pipe around the first supply pipe to suck the second solution.

The wet etching nozzle may further comprise a detector configured to detect an optical signal from the substrate, and the detector includes a light source configured to irradiate the substrate with a first light and a sensor configured to sense a second light that is produced through reflection of the first light from the substrate.

The first supply pipe, the second supply pipe, and the detector are successively arranged in one direction.

The detector is arranged on both sides around the first supply pipe.

In another aspect of the present invention, there is provided a wet etching nozzle comprising a first supply pipe configured to supply an etching solution to a part of a substrate including an etched layer, a first suction pipe configured to suck the etching solution from the substrate, and a detector including a light source configured to irradiate the substrate with a first light and a sensor configured to sense a second light that is produced through reflection of the first light from the substrate, the detector being used to confirm whether the detector is positioned on an upper portion of the substrate.

The wet etching nozzle may further comprise a second supply pipe configured to supply a cleaning solution to the substrate, a second suction pipe configured to suck the cleaning solution from the substrate, and a third supply pipe configured to supply a drying gas to the substrate.

In still another aspect of the present invention, there is provided a semiconductor manufacturing equipment comprising a substrate holder on which a substrate including an etched layer is positioned, a nozzle arranged on the substrate holder and including a first supply pipe configured to supply a first solution for etching the etched layer, a first suction pipe configured to suck the first solution from the substrate, a second supply pipe configured to supply a second solution for cleaning the etched layer, and a second suction pipe configured to suck the second solution from the substrate, and a controller operationally connected to the nozzle and/or the substrate holder, the controller configured to adjust an etched amount of the etched layer.

The nozzle further comprises a third supply pipe configured to supply a third solution for cleaning the substrate, a third suction pipe configured to suck the third solution from the substrate, and a fourth supply pipe configured to supply a gas for drying the substrate.

The semiconductor manufacturing equipment may further comprise a detector connected to the controller and configured to detect an optical signal from the substrate.

The controller is configured to determine whether the substrate is positioned on a lower portion of the detector using the optical signal.

The controller configured to measure a thickness of the etched layer using the optical signal.

The controller configured to change a relative speed between the nozzle and the substrate holder according to a thickness of the etched layer that is positioned on a lower portion of the first supply pipe.

The controller configured to change a concentration of the first solution according to a thickness of the etched layer that is positioned on a lower portion of the first supply pipe.

The first supply pipe, the first suction pipe, the second supply pipe, and the second suction pipe are in the form of circles, and the first supply pipe, the first suction pipe, the second supply pipe, and the second suction pipe are arranged in the form of concentric circles.

The first supply pipe, the first suction pipe, the second supply pipe, and the second suction pipe are successively arranged in one direction.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram explaining semiconductor manufacturing equipment according to an embodiment of the present invention;

FIGS. 2 to 4 are views explaining a wet etching nozzle according to another embodiment of the present invention;

FIG. 5 is a view explaining a wet etching nozzle according to still another embodiment of the present invention;

FIGS. 6 and 7 are views explaining a wet etching nozzle according to still another embodiment of the present invention;

FIG. 8 is a view explaining a wet etching nozzle according to still another embodiment of the present invention; and

FIGS. 9 to 14 are views explaining a wet etching method according to still another embodiment of the present invention.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or example terms provided herein is intended merely to better illuminate the invention and is not a limitation on the scope of the invention unless otherwise specified. Further, unless defined otherwise, all terms defined in generally used dictionaries may not be overly interpreted.

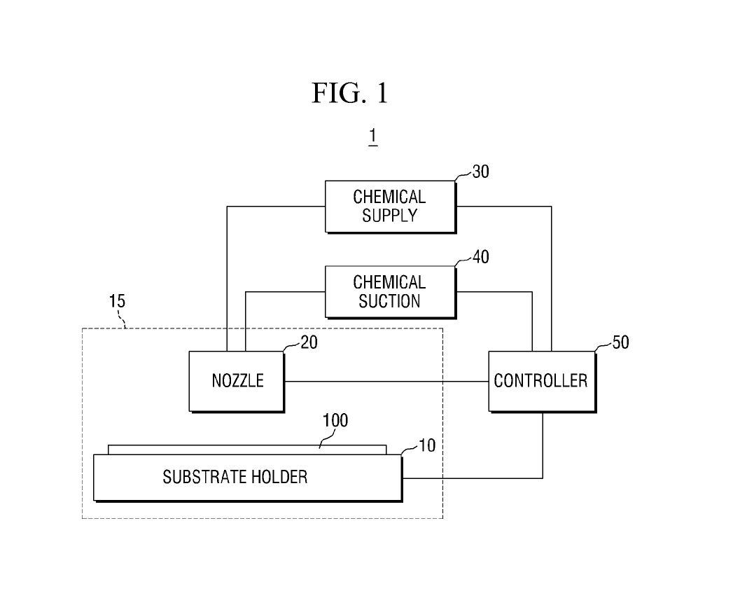

Hereinafter, referring to FIGS. 1 to 8, a wet etching nozzle and semiconductor manufacturing equipment including the same according to embodiments of the present invention will be described.

FIG. 1 is a block diagram explaining semiconductor manufacturing equipment according to an embodiment of the present invention.

Referring to FIG. 1, semiconductor manufacturing equipment 1 may include a substrate holder 10, a nozzle 20, a chemical supply unit 30, a chemical suction unit 40, and a controller 50.

The semiconductor manufacturing equipment 10 according to an embodiment of the present invention may be, for example, wet etching equipment, and more specifically, may be equipment that can perform local wet etching.

The substrate holder 10 is a place on which an etched substrate 100 is positioned.

The substrate holder 10 may move upward, downward, leftward, and rightward to move the substrate 100. Further, the substrate holder 10 may be rotated to rotate the substrate 100.

The substrate holder 10 may be connected to the controller 50. The movement of the substrate holder 10 may be controlled by the controller 50. Through the movement of the substrate holder 10, a relative position between the substrate 100 and the nozzle 20 can be adjusted.

During the operation of the semiconductor manufacturing equipment 1, the substrate holder 10 may fix the substrate 100 to prevent the substrate 100 from moving or seceding from the substrate holder 10. For example, the substrate holder 10 may fix the substrate 100 in a vacuum, but is not limited thereto.

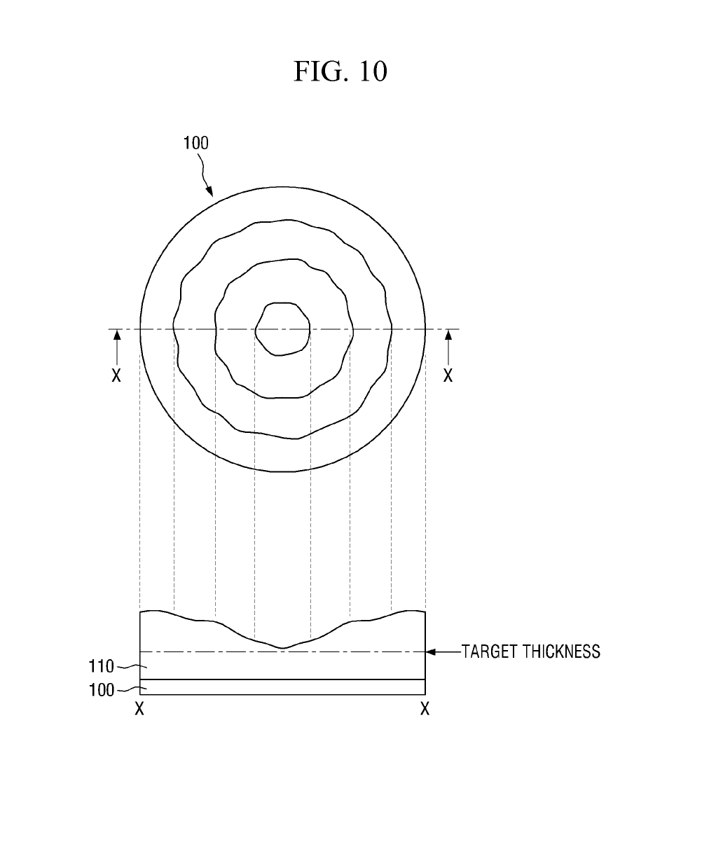

The substrate 100 is arranged on the substrate holder 10. The substrate 100 may include an etched layer (see 110 in FIG. 10) to be etched. The substrate 100 may be or may not be provided with a semiconductor device circuit pattern formed thereon.

The substrate 100 may be made of, for example, bulk silicon or SOI (Silicon-On-Insulator). In an embodiment, the substrate 100 may be a silicon substrate or may include another material, for example, silicon germanium, indium antimonide, lead telluride, indium arsenide, indium phosphide, gallium arsenide, or gallium antimonide. Further, the substrate 100 may be a rigid substrate, such as a glass substrate for display, or a flexible substrate, but is not limited thereto.

The nozzle 20 is arranged on the substrate holder 10. The nozzle 20 may be connected to the chemical supply unit 30 and the chemical suction unit 40. Further, the nozzle 20 may be connected to the controller 50.

The nozzle 20 may be provided with a chemical material from the chemical supply unit 30. The nozzle 20 may supply the provided chemical material to the substrate 100 that is arranged on the substrate holder 10. For example, the nozzle 20 may supply the chemical material to a local area of the substrate 100.

Further, the nozzle 20 may suck the chemical material that remains on the substrate 100 from the substrate 100. The nozzle 20 may transfer the sucked chemical material to the chemical suction unit 40. For example, the nozzle 20 may suck the chemical material from a local area of the substrate 100.

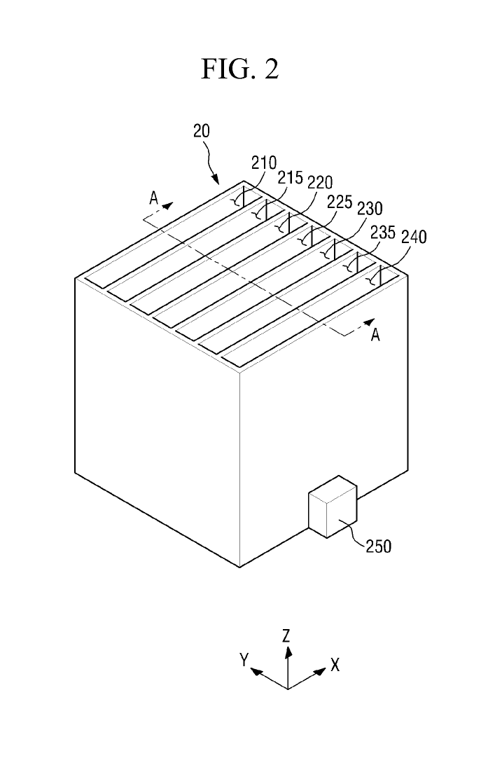

That is, the nozzle 20 may supply the chemical material onto the substrate 100 that is positioned on the substrate holder 10 or may suck the chemical material that remains on the substrate 100. Further, the nozzle 20 may simultaneously perform supplying of the chemical material onto the substrate 100 and sucking of the chemical material from the substrate 100. The detailed contents of the nozzle 20 will be described with reference to FIGS. 2 to 8.

The supplying of the chemical material through the nozzle 20 and the sucking of the chemical material may be controlled by the controller 50, but are not limited thereto.

The nozzle 20 may move upward, downward, leftward, and rightward. As the nozzle 20 moves, a relative position between the substrate 100 and the nozzle 20 can be adjusted. The movement of the nozzle 20 may be controlled by the controller 50.

A chamber 15 may be a place where a providing process of semiconductor manufacturing equipment, e.g., an etching process, is performed. The nozzle 20 and the substrate holder 10 may be positioned in the chamber 15.

The chemical supply unit 30 may be connected to the nozzle 20, and may be connected to the controller 50. The providing of the chemical material through the chemical supply unit 30 may be controlled by the controller 50.

The chemical supply unit 30 may supply various chemical materials to the nozzle 20. For example, the chemical supply unit 30 may provide an etching solution, cleaning solution, and a drying gas to the nozzle 20.

The etching solution is a solution that etches an etched layer that is included in the substrate 100. The etching solution may differ depending on the kind of the etched layer. The etching solutions that differ depending on the kinds of the etched layers may be separated from each other. The etching solutions may be stored in separate supply containers that are connected to the semiconductor manufacturing equipment or may be provided through utility lines of a FAB.

The cleaning solution is a solution that cleans a portion that is etched by the etching solution. That is, the cleaning solution may remove the chemical material that may remain on the etched portion. Depending on what etching solution is used, the number of cleaning solutions and the kinds thereof may differ. For example, if two kinds of cleaning solutions are used, one cleaning solution may be, for example, deionized (DI) water and the other cleaning solution may be, for example, isopropyl alcohol (IPA). However, the kinds of the cleaning solutions are not limited thereto.

The different kinds of cleaning solutions may be separated from each other. The etching solutions may be stored in separate supply containers connected to the semiconductor manufacturing equipment or may be provided through the utility lines of the FAB.

The drying gas dries the portion that is cleaned by the cleaning solution. The drying gas may be stored in a separate supply container connected to the semiconductor manufacturing equipment or may be provided through a utility line of the FAB.

The chemical suction unit 40 may be connected to the nozzle 20. Further, the chemical suction unit 40 may be connected to the controller 50, but is not limited thereto.

The chemical suction unit 40 may receive the sucked chemical material that is transferred from the substrate 100. The chemical suction unit 40 may receive the etching solution, the cleaning solution, and the drying gas from the nozzle.

For example, the chemical suction unit 40 may separately suck the etching solution and the cleaning solution. That is, the chemical suction unit 40 may have an etching solution suction line and a cleaning solution suction line that are separated from each other. Since a mixture of the etching solution and the cleaning solution may cause explosion, the chemical suction unit 40 may separately suck the etching solution and the cleaning solution. Further, to recover and reuse the etching solution and/or the cleaning solution, the chemical suction unit 40 may separately suck the etching solution and the cleaning solution in order to avoid a separate separation process.

In an embodiment, the chemical suction unit 40 may suck the etching solution and the cleaning solution through one line without separately sucking the etching solution and the cleaning solution. That is, a line for sucking the etching solution and a line for sucking the cleaning solution may be configured as one line. If a mixture of the etching solution and the cleaning solution does not carry a risk of explosion or the etching solution and the cleaning solution is not going to be reused, the line for sucking the etching solution and the line for sucking the cleaning solution may be configured as one line.

The controller 50 may be connected to the substrate holder 10, the nozzle 20, and the chemical supply unit 30. FIG. 1 illustrates that the controller 50 is connected to the chemical suction unit 40, but is not limited thereto.

For example, the controller 50 may adjust an etched amount of the etched layer that is included in the substrate 100. In an embodiment, the controller 50 may adjust the etched amount of the etched layer according to the position of the etched layer.

For example, a method in which the controller 50 adjusts the etched amount of the etched layer according to the position of the etched layer may be as follows.

First, in accordance with the thickness of the etched layer on the lower portion of the nozzle 20 that provides the etching solution, the controller 50 changes the relative speed between the nozzle 20 and the substrate holder 10.

In an embodiment, it is assumed that the concentration of the etching solution that is supplied through the nozzle 20 is constant. If the concentration of the etching solution is constant, it may be considered that the etch rate of the etched layer is constant. If the etched layer to be etched is thick, the controller 50 increases a time required to etch the etched layer through lowering of the relative speed between the nozzle 20 and the substrate holder 10. If the etched layer to be etched is thin, the controller 50 decreases the time required to etch the etched layer through heightening of the relative speed between the nozzle 20 and the substrate holder 10.

Since the controller 50 can control the movement of the nozzle 20 and/or the substrate holder 10, the controller 50 can change the relative speed between the nozzle 20 and the substrate holder 10.

Through this, the etched layer may be etched with different etched amounts for respective positions of the etched layer. Accordingly, in an embodiment, the thickness of the etched layer of which the etching process is completed becomes entirely uniform.

Next, in accordance with the thickness of the etched layer on the lower portion of the nozzle 20 that provides the etching solution, the controller 50 changes the concentration of the etching solution that is supplied from the nozzle 20.

In an embodiment, it is assumed that the relative speed between the nozzle 20 and the substrate holder 10 is constant. If the relative speed between the nozzle 20 and the substrate holder 10 is constant, it may be considered that the time required to etch the etched layer through the etching solution is constant.

If the etched layer to be etched is thick, the controller 50 increases the etch rate of the etched layer through increasing of the concentration of the etching solution that is provided from the chemical supply unit 30 to the nozzle 20. If the etched layer to be etched is thin, the controller 50 decreases the etch rate of the etched layer through decreasing of the concentration of the etching solution that is provided from the chemical supply unit 30 to the nozzle 20.

Through this, the etched layer may be etched with different etched amounts for respective positions of the etched layer. Accordingly, the thickness of the etched layer of which the etching process is completed becomes entirely uniform.

The controller 50 may determine whether the substrate 100 is positioned on the lower portion of the nozzle 20. Accordingly, if the substrate 100 is positioned on the lower portion of the nozzle 20, the nozzle 20 supplies the etching solution to the substrate 100. However, if the substrate 100 is not positioned on the lower portion of the nozzle 20, the nozzle 20 does not supply the etching solution to the substrate 100.

The controller 50 may measure the thickness of the etched layer of which the local etching process is completed. Through measurement of the thickness of the etched layer of which the etching process is completed, the controller 50 can correct the etching amount of the etched layer on an area on which the etching is to be performed.

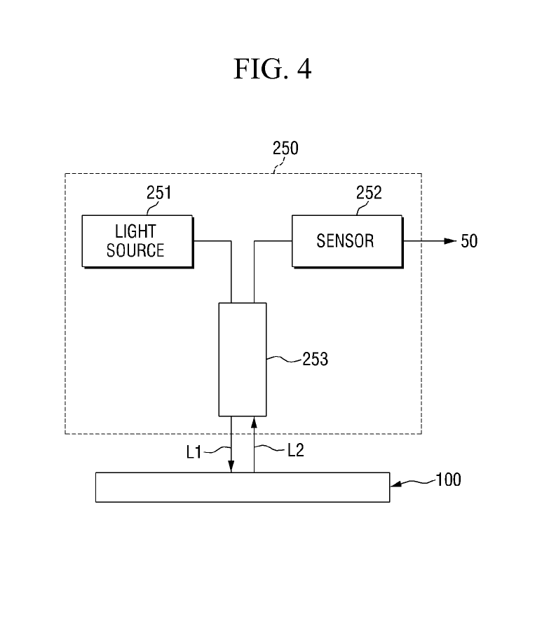

A case where the controller 50 determines whether the substrate 100 is positioned on the lower portion of the nozzle 20 and a case where the controller 50 measures the thickness of the etched layer of which the local etching process is completed will be described with reference to FIG. 4.

Hereinafter, referring to FIGS. 2 to 8, the configuration of a nozzle 20 according to another embodiment of the present invention will be described.

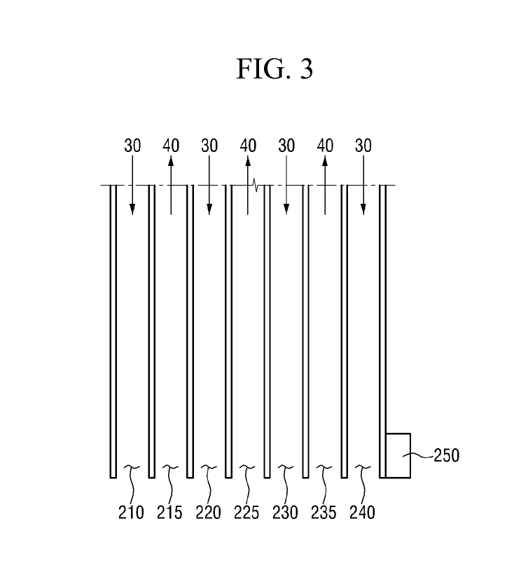

FIG. 2 is a perspective view illustrating a wet etching nozzle, and FIG. 3 is a cross-sectional view cut along line A-A of FIG. 2. FIG. 4 is a diagram explaining the operation of a detector.

Referring to FIGS. 2 and 3, a wet etching nozzle 20 according to another embodiment of the present invention may include a first supply pipe 210, a second supply pipe 220, a fourth suction pipe 245, and a second suction pipe 225.

In FIG. 2, the wet etching nozzle 20 may further include a third supply pipe 230, a fourth supply pipe 240, a third suction pipe 235, and a first detector 250, but is not limited thereto.

In a plan view, FIG. 2 illustrates that the first to fourth supply pipes 210, 220, 230, and 240 and the first to third suction pipes 215, 225, and 235 are in a slit shape that extends in a first direction X, but are not limited thereto.

The first to fourth supply pipes 210, 220, 230, and 240 and the first to third suction pipes 215, 225, and 235 are arranged in a second direction Y.

The fourth suction pipe 245 may be arranged between the first supply pipe 210 and the second supply pipe 220, the second suction pipe 225 may be arranged between the second supply pipe 220 and the third supply pipe 230, and the third suction pipe 235 may be arranged between the third supply pipe 230 and the fourth supply pipe 240.

In other words, the first supply pipe 210, the fourth suction pipe 245, the second supply pipe 220, the second suction pipe 225, the third supply pipe 230, the third suction pipe 235, and the fourth supply pipe 240 may be successively arranged in the second direction Y.

A suction pipe that can suck a provided chemical material may be positioned between supply pipes that provide the chemical material onto the substrate.

The first supply pipe 210 supplies a first solution to the substrate 100 (in FIG. 1) that include an etched layer. The first solution may be an etching solution that can etch the etched layer. That is, the first supply pipe 210 may supply the etching solution onto the substrate.

For example, the first supply pipe 210 may supply the first solution to a partial area of the etched layer. This is because the first solution does not entirely etch the etched layer, but etches a local portion of the etched layer.

The first supply pipe 210 may be connected to the chemical supply unit 30. That is, the first solution that the first supply pipe 210 supplies to the substrate 100 may be an etching solution that is provided from the chemical supply unit 30.

For example, if the etched layer is made of silicon oxide, the first solution that is provided through the first supply pipe 210 may include, for example, hydrofluoric acid (HF) or buffered oxide etch (BOE), but is not limited thereto.

If the etched layer is made of polysilicon, the first solution that is provided through the first supply pipe 210 may be, for example, a mixed solution of HF and nitric acid (HNO₃), and if the etched layer is made of silicon nitride, the first solution that is provided through the first supply pipe 210 may be, for example, one of high-concentration (conc.) HF, a mixed solution of phosphoric acid (H₃PO₄) and HF, and a mixed solution of sulfuric acid (H₂SO₄) and HF, but is not limited thereto.

The first suction pipe 215 sucks the first solution from the substrate. In other words, the first suction pipe 215 may suck the first solution that the first supply pipe 210 provides to the substrate.

Further, the first suction pipe 215 may suck not only the first solution that is provided from the first supply pipe 210 but also a part of a second solution that the second supply pipe 220 provides to the substrate.

The first suction pipe 215 may be connected to the chemical suction unit 40. That is, the first solution that the first suction pipe 215 sucks from the substrate may be transferred to the chemical suction unit 40.

The second supply pipe 220 supplies the second solution to a partial area of the etched layer. The second solution may be a cleaning solution that can clean the etched layer. That is, the second supply pipe 220 may supply the cleaning solution to the substrate.

Although the cleaning solution is sucked by the first suction pipe 215, it cleans the first solution that may remain on the substrate.

The second supply pipe 220 may be connected to the chemical supply unit 30. That is, the second solution that the second supply pipe 220 supplies to the substrate 100 may be a cleaning solution that is provided from the chemical supply unit 30.

For example, the second solution that is provided through the second supply pipe may be deionized water, but is not limited thereto.

The second suction pipe 225 sucks the second solution from the substrate. In other words, the second suction pipe 225 may suck the second solution that the second supply pipe provides to the substrate.

The second suction pipe 225 may suck not only the second solution that is provided from the second supply pipe 220 but also a part of a third solution that the third supply pipe 230 provides to the substrate.

The second suction pipe 225 may be connected to the chemical suction unit 40. That is, the second solution that the second suction pipe 225 sucks from the substrate may be transferred to the chemical suction unit 40.

The third supply pipe 230 supplies the third solution to a partial area of the etched layer. The third solution may be a cleaning solution that can clean the etched layer. That is, the third supply pipe 230 may supply the cleaning solution to the substrate.

Although the cleaning solution is sucked by the second suction pipe 225, it cleans the second solution that may remain on the substrate or stains that are caused by the second solution.

The third supply pipe 230 may be connected to the chemical supply unit 30. That is, the third solution that the third supply pipe 230 supplies to the substrate 100 may be a cleaning solution that is provided from the chemical supply unit 30.

For example, the third solution that is provided through the third supply pipe 230 may be a chemical material that can be well mixed with a polar material and can be easily evaporated. For example, the third solution may be isopropyl alcohol (IPA), but is not limited thereto.

The third suction pipe 235 sucks the third solution from the substrate. In other words, the third suction pipe 235 may suck the third solution that the third supply pipe 230 provides to the substrate.

Further, the third suction pipe 235 may suck not only the third solution that is provided from the third supply pipe 230 but also a part of gas that the fourth supply pipe 240 provides to the substrate.

The third suction pipe 235 may be connected to the chemical suction unit 40. That is, the third solution that the third suction pipe 235 sucks from the substrate may be transferred to the chemical suction unit 40.

The fourth supply pipe 240 may supply a gas for drying the etched layer to the substrate. That is, the fourth supply pipe 240 may supply a drying gas to a partial area of the etched layer. That is, the drying gas that the fourth supply pipe 240 supplies to the substrate 100 may be a gas that is provided from the chemical supply unit 30.

Although not illustrated in FIG. 2, a separate suction pipe may be provided to suck the drying gas that is provided through the fourth supply pipe 240, but is not limited thereto. That is, an additional suction pipe may be arranged on a side surface of the fourth supply pipe 240 in the second direction Y.

In another embodiment of the present invention, it is described that there is one supply pipe that provides the etching solution in the wet etching nozzle, but is not limited thereto. That is, a plurality of supply pipes may be provided to supply the etching solution, and thus a plurality of suction pipes may be provided to suck the etching solution.

Further, it is described that two supply pipes are provided to supply the cleaning solution, but is not limited thereto. That is, only one supply pipe may be provided, or three or more supply pipes may be provided.

The first detector 250 may be arranged on the side surface of the fourth supply pipe 240 in the second direction Y. That is, in FIG. 2, the first supply pipe 210, the second supply pipe 220, the third supply pipe 230, the fourth supply pipe 240, and the first detector 250 may be successively arranged in the second direction Y.

That is, the first detector 250 may be arranged on the side surface of the first supply pipe 220 in the second direction Y, and the first supply pipe 210 may be positioned between the first detector 250 and the second supply pipe 220 may be positioned between the first detector 250 and the second supply pipe 220.

The first detector 250 may detect an optical signal that comes out from the substrate. The first detector 250 will be described in detail with reference to FIG. 4.

Referring to FIG. 4, the first detector 250 may include a light source 251, a sensor 252, and a connector 253.

The light source 251 irradiates the substrate 100 with a first light L1. The first light L1 is irradiated onto the substrate 100 through the connector 253. The first light L1 is reflected by the substrate 100 to form a second light L2. The second light L2 moves to the sensor 252 through the connector 253. Through this, the sensor 252 senses the second light L2.

The light source 251 may include, for example, various kinds of lamps or lasers that emit light. More specifically, the lamp may include an LED (Light Emitting Diode) lamp, a tungsten halogen lamp, or a xenon lamp, and the laser may include helium neon (HeNe) laser, an argon (Ar) laser, or a laser diode (LD) having various wavelength, but are not limited thereto.

The sensor 252 senses light and generates an electrical signal. That is, the sensor 252 senses an optical signal that is the second light L2 and generates an electrical signal. In an embodiment, the sensor 252 may include, for example, a photo transistor and a photo diode, such as a PIN diode or an APD diode, but is not limited thereto.

The electrical signal that is generated from the sensor 252 that senses the second light L2 that is an optical signal may be transferred to the controller 50 (in FIG. 1) that is connected to the first detector 250.

The controller 50 may determine whether the substrate 100 is positioned on a lower portion of the first detector 250 using the electrical signal that is transferred as described above. That is, the controller 50 may determine whether the substrate 100 is positioned on the lower portion of the first detector 250 using the second light L2 that is the optical signal sensed by the sensor 252.

In other words, the controller 50 may confirm whether the first detector 250 is positioned on an upper portion of the substrate 100 using the optical signal that is generated from the substrate 100.

Further, the controller 50 may measure the thickness of the etched layer that is positioned on the lower portion of the first detector 250 using the electrical signal that is generated from the sensor 252.

In other words, the controller 50 may measure the thickness of the etched layer that is positioned on the lower portion of the first detector 250 using the optical signal that is generated from the substrate 100.

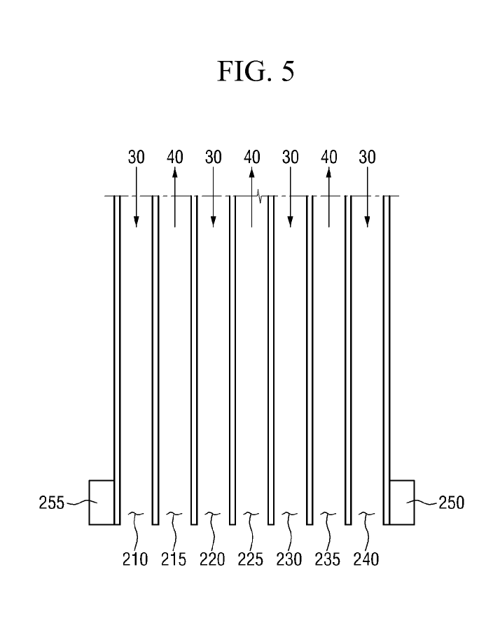

FIG. 5 is a view explaining a wet etching nozzle according to still another embodiment of the present invention. A wet etching nozzle according to still another embodiment of the present invention will be described around the different point from the embodiment as described above using FIGS. 2 to 4.

Referring to FIG. 5, a wet etching nozzle 20 further includes a second detector 255.

The second detector 255 may be arranged on a side surface of the first supply pipe 210. The first supply pipe 210 may be positioned between the second detector 255 and the second supply pipe 220.

Further, the first detector 250 and the second detector 255 are arranged on both sides of the first supply pipe 210.

The first detector 250 and the second detector 255 may detect the optical signal that comes out from the substrate. Using the optical signal, the controller 50 (in FIG. 1) can determine whether the substrate 100 is positioned on the lower portions of the detectors 250 and 255, and can measure the thickness of the etched layer that is positioned on the lower portions of the detectors 250 and 255.

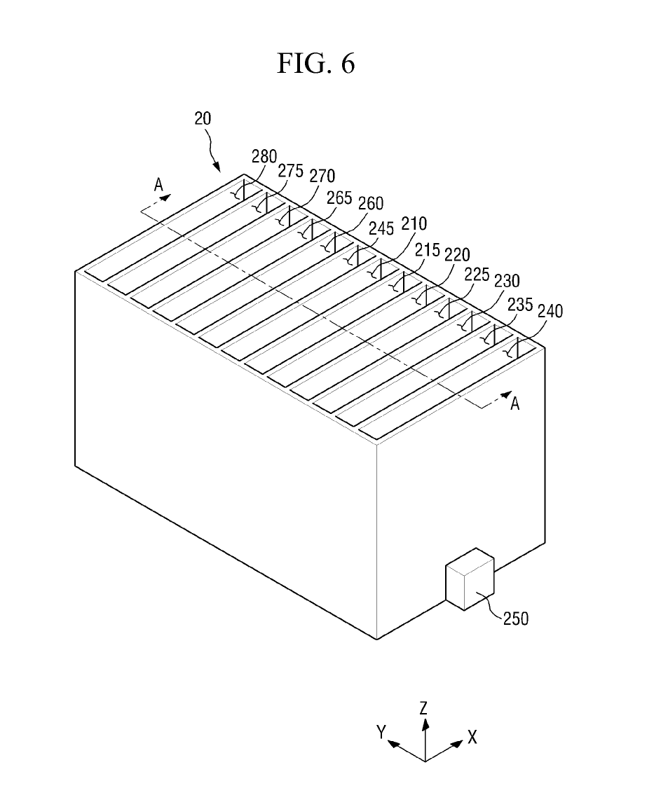

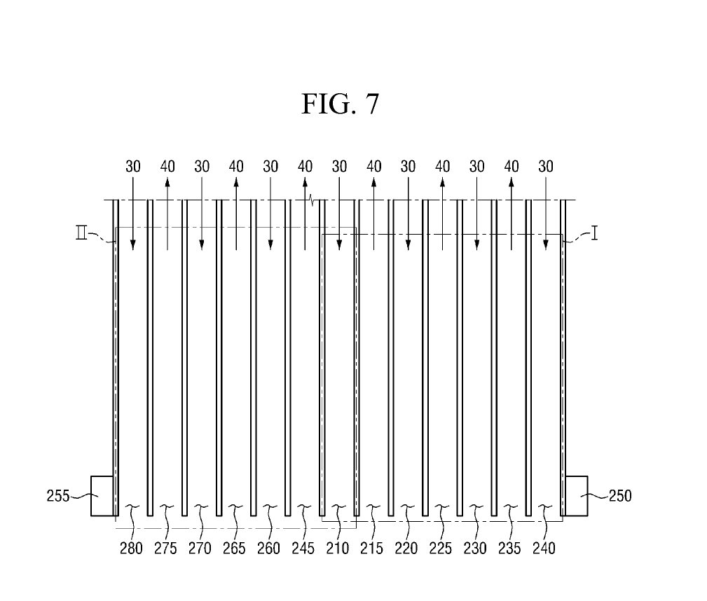

FIGS. 6 and 7 are views explaining a wet etching nozzle according to still another embodiment of the present invention. A wet etching nozzle according to still another embodiment of the present invention will be described around the different point from the embodiment as described above using FIG. 5.

FIG. 6 is a perspective view illustrating a wet etching nozzle, and FIG. 7 is a cross-sectional view cut along line A-A of FIG. 6.

Referring to FIGS. 6 and 7, the wet etching nozzle 20 further includes a fifth supply pipe 260, a sixth supply pipe 270, a seventh suction pipe 280, a fourth suction pipe 245, a fifth suction pipe 265, and a sixth suction pipe 275.

In a plan view, FIG. 6 illustrates that the first to seventh supply pipes 210, 220, 230, 240, 260, 270, and 280 and the first to sixth suction pipes 215, 225, 235, 245, 265, and 275 are in a slit shape that extends in the first direction X, but are not limited thereto.

The first to seventh supply pipes 210, 220, 230, 240, 260, 270, and 280 and the first to sixth suction pipes 215, 225, 235, 245, 265, and 275 are arranged in the second direction Y.

The fourth suction pipe 245 is arranged between the first supply pipe 210 and the fifth supply pipe 260, the fifth suction pipe 265 is arranged between the fifth supply pipe 260 and the sixth supply pipe 270, and the sixth suction pipe 275 is arranged between the sixth supply pipe 270 and the seventh supply pipe 280.

In other words, the fourth suction pipe 245 is arranged to correspond to the first suction pipe 215 around the first supply pipe 210, and the fifth supply pipe 260 is arranged to correspond to the second supply pipe 220 around the first supply pipe 210. The fifth suction pipe 265 and the sixth suction pipe 275 are arranged to correspond to the second suction pipe 225 and the third suction pipe 235 around the first supply pipe 210, respectively. The sixth supply pipe 270 and the seventh supply pipe 280 are arranged to correspond to the third supply pipe 230 and the fourth supply pipe 240 around the first supply pipe 210, respectively.

That is, in the wet etching nozzle 20, the suction pipes 215, 225, 235, 245, 265, and 275 and the supply pipes 220, 230, 240, 260, 270, and 280 may be symmetrically arranged about the first supply pipe 210.

The fourth suction pipe 245 sucks the first solution from the substrate. In other words, the fourth suction pipe 245 may suck the first solution that the first supply pipe 210 provides to the substrate.

Further, the fourth suction pipe 245 may suck not only the first solution that is provided from the first supply pipe 210 but also a part of a second solution that the fifth supply pipe 260 provides to the substrate.

The fourth suction pipe 245 may be connected to the chemical suction unit 40. That is, the first solution that the fourth suction pipe 245 sucks from the substrate may be transferred to the chemical suction unit 40.

The fifth supply pipe 260 supplies the second solution to a partial area of the etched layer. The second solution may be a cleaning solution that can clean the etched layer.

The fifth supply pipe 260 may be connected to the chemical supply unit 30. That is, the second solution that the fifth supply pipe 260 supplies to the substrate 100 may be a cleaning solution that is provided from the chemical supply unit 30.

The fifth suction pipe 265 sucks the second solution from the substrate. In other words, the fifth suction pipe 265 may suck the second solution that the fifth supply pipe 260 provides to the substrate.

Further, the fifth suction pipe 265 may suck not only the second solution that is provided from the fifth supply pipe 260 but also a part of the third solution that the sixth supply pipe 270 provides to the substrate.

The fifth suction pipe 265 may be connected to the chemical suction unit 40. That is, the second solution that the fifth suction pipe 265 sucks from the substrate may be transferred to the chemical suction unit 40.

The sixth supply pipe 270 supplies the third solution to a partial area of the etched layer. The third solution may be a cleaning solution that can clean the etched layer.

The sixth supply pipe 270 may be connected to the chemical supply unit 30. That is, the third solution that the sixth supply pipe 270 supplies to the substrate 100 may be a cleaning solution that is provided from the chemical supply unit 30.

The sixth suction pipe 275 sucks the third solution from the substrate. In other words, the sixth suction pipe 275 may suck the third solution that the sixth supply pipe 270 provides to the substrate.

Further, the sixth suction pipe 275 may suck not only the third solution that is provided from the sixth supply pipe 270 but also a part of gas that the seventh supply pipe 280 provides to the substrate.

The sixth suction pipe 275 may be connected to the chemical suction unit 40. That is, the third solution that the sixth suction pipe 275 sucks from the substrate may be transferred to the chemical suction unit 40.

The seventh supply pipe 280 may supply a gas for drying the etched layer to the substrate. That is, the seventh supply pipe 280 may supply a drying gas to the partial area of the etched layer.

The seventh supply pipe 280 may be connected to the chemical supply unit 30. That is the drying gas that the seventh supply pipe 280 supplies to the substrate 100 may be a gas that is provided from the chemical supply unit 30.

The second detector 255 may be arranged on the side surface of the seventh supply pipe 280 in the second direction Y. That is, in FIG. 6, the first supply pipe 210, the fifth supply pipe 260, the sixth supply pipe 270, the seventh supply pipe 280, and the second detector 255 may be successively arranged in the second direction Y.

The wet etching nozzle 20 may be divided into two parts around the first supply pipe 210. A first area I of the wet etching nozzle 20 may include the first to fourth supply pipes 210, 220, 230, and 240 and the first to third suction pipes 215, 225, and 235. Further, a second area II of the wet etching nozzle 20 may include the fifth to seventh supply pipes 260, 270, and 280 and the fourth to sixth suction pipes 245, 265, and 275.

When the wet etching nozzle 20 moves from the fourth supply pipe 240 to the direction of the first supply pipe 210, the first area I of the wet etching nozzle 20 may be operated. When the wet etching nozzle 20 moves from the seventh supply pipe 280 to the direction of the first supply pipe 210, the second area II of the wet etching nozzle 20 may be operated.

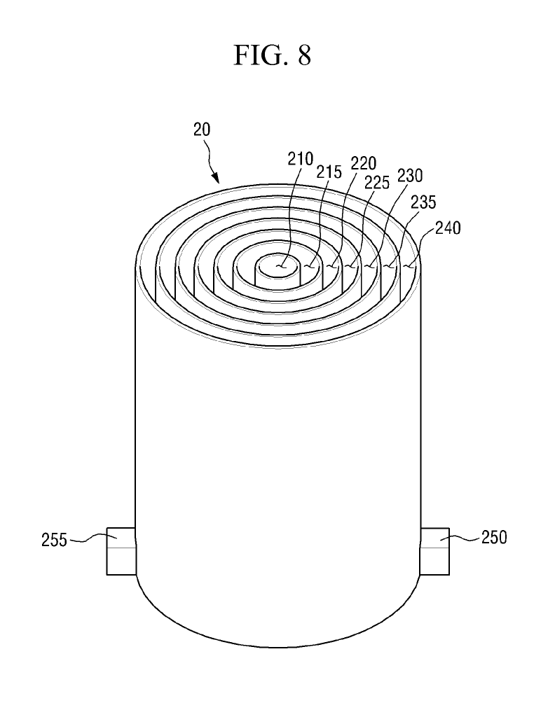

FIG. 8 is a view explaining a wet etching nozzle according to still another embodiment of the present invention. The wet etching nozzle according to still another embodiment of the present invention will be described around the different point from the embodiment as described above using FIG. 5.

Referring to FIG. 8, the first supply pipe 210, the second supply pipe 220, the third supply pipe 230, the fourth supply pipe 240, the first suction pipe 215, the second suction pipe 225, and the third suction pipe 235 may be in a circular shape.

The first supply pipe 210, the second supply pipe 220, the third supply pipe 230, the fourth supply pipe 240, the first suction pipe 215, the second suction pipe 225, and the third suction pipe 235 may be arranged in the form of concentric circles.

The first supply pipe 210 is arranged in a center portion of the wet etching nozzle 20, and the second supply pipe 220, the third supply pipe 230, and the fourth supply pipe 240 are successively arranged in a radial direction around the first supply pipe 210.

The first suction pipe 215 is arranged between the first supply pipe 210 and the second supply pipe 220, the second suction pipe 225 is arranged between the second supply pipe 220 and the third supply pipe, and the third suction pipe 235 is arranged between the third supply pipe 230 and the fourth supply pipe 240.

The first detector 250 and the second detector 255 may be arranged on the outside of the fourth supply pipe 240.

Referring to FIGS. 1 and 9 to 14, a wet etching method according to still another embodiment of the present invention will be described.

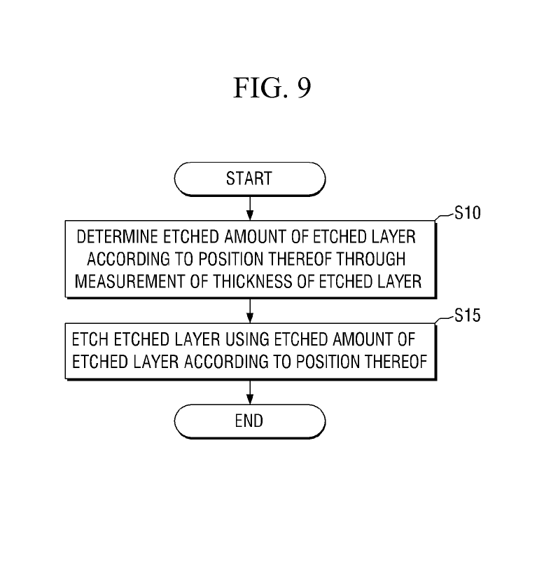

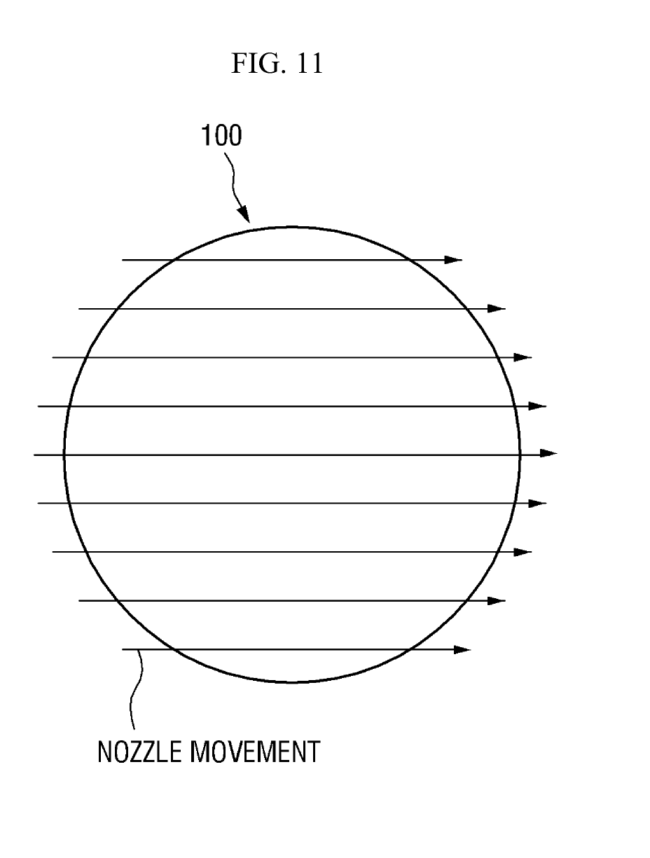

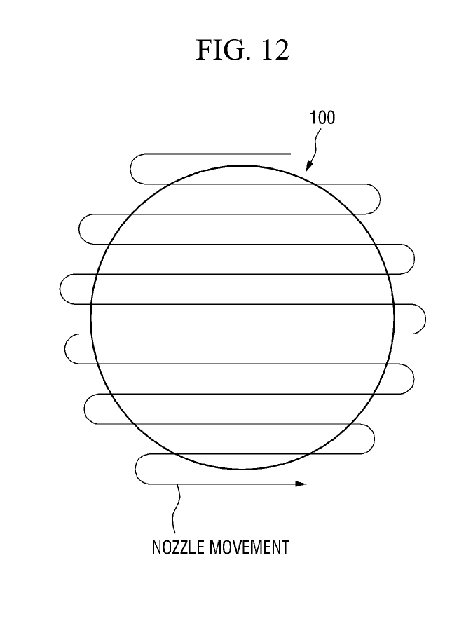

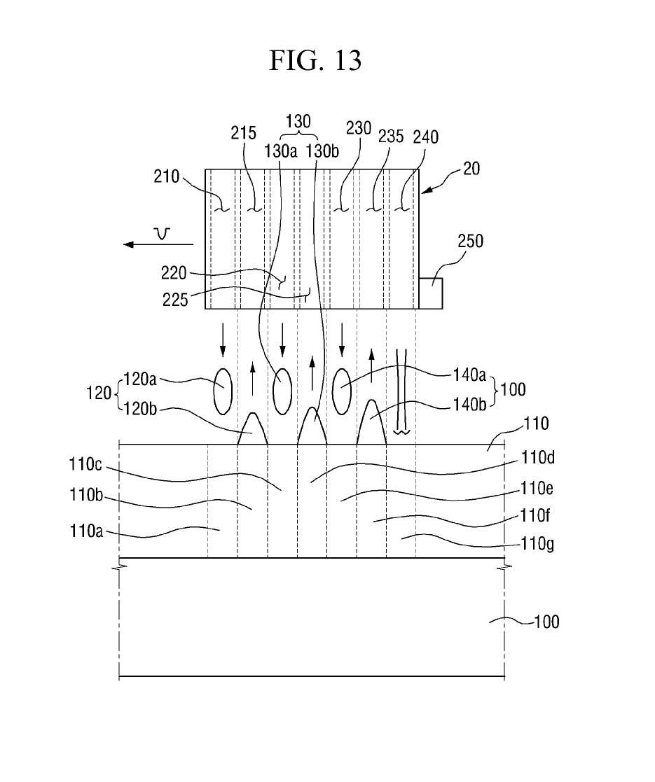

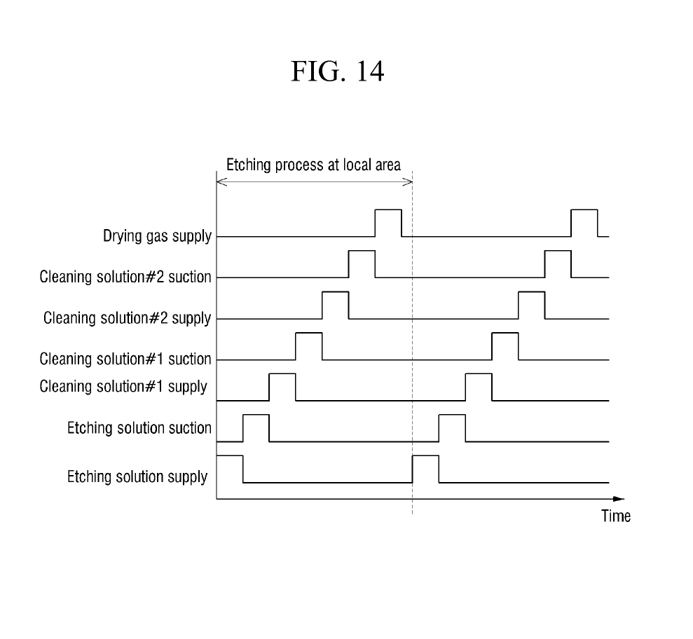

FIGS. 9 to 14 are views explaining a wet etching method according to still another embodiment of the present invention. Specifically, FIG. 9 is a flowchart explaining a wet etching method according to still another embodiment of the present invention, and FIG. 10 is a view explaining the wet etching method according to still another embodiment of the present invention. FIGS. 11 and 12 are views explaining a relative movement between the substrate and the nozzle for wet etching. FIG. 13 is a view explaining supply and suction of solutions in a local area. FIG. 14 is a timing diagram explaining supply and suction of solutions when a local wet etching is performed in a predetermined area.

Referring to FIGS. 9 and 10, an etched amount of the etched layer according to the position of the etched layer 110 is determined through measurement of the thickness of the etched layer 110 that is deposited on the substrate 100 (S10).

The thickness of the etched layer 110 according to the position of the etched layer 110 is measured through entire scanning of the substrate 100. Even if the deposition condition of the etched layer 110 is optimized, there may be a deviation in thickness of the deposited etched layer 110 according to the position thereof.

FIG. 10 illustrates that the thickness of the etched layer 110 deposited on the center portion of the substrate 100 is smallest, and the thickness of the etched layer 110 deposited on the edge portion of the substrate 100 is largest. However, this is merely example, and the thicknesses of the etched layer 110 are not limited thereto.

Thereafter, to satisfy the target thickness, it is determined how deep the etched layer 110 is to be etched according to the position of the etched layer 110. That is, the etched amount of the etched layer 110 is determined according to the position thereof.

Referring to FIGS. 1, 9, and 11 to 14, the substrate 100 that includes the etched layer 110 is arranged on the substrate holder 10. Thereafter, the etched layer 110 is etched using the etched amount of the etched layer 110 that is determined according to the position thereof (S15).

The etched amount of the etched layer 110 may differ depending on the position thereof. Accordingly, for local wet etching, the etched layer 110 is locally wet-etched during movement of the nozzle 20 and/or the substrate holder 10. That is, while the nozzle 20 and the substrate 100 move relatively, the etched layer is locally wet-etched.

FIG. 11 shows that the etched layer 110 is locally wet-etched while the nozzle 20 moves in one direction. FIG. 12 shows that the etched layer 110 is locally wet-etched while the nozzle 20 moves in zigzag.

Referring to FIGS. 11 and 12, it is illustrated that the local wet etching is performed while the nozzle 20 scans the etched layer 110 substantially in a straight line. However, but the etching type is not limited thereto.

Further, FIGS. 11 and 12 illustrate that the substrate 100 is fixed and the nozzle 20 moves to perform the local wet etching, but are not limited thereto. That is, the nozzle 20 may be fixed and the substrate 100 may move. Further, both the substrate 100 and the nozzle 20 may move.

Referring to FIG. 13, it is described how the etched layer 110 that includes areas that are successively adjacent to each other is locally wet-etched.

The etched layer 110 includes first to seventh areas 110a, 110b, 110c, 110d, 110e, 110f, and 110g that are successively adjacent to each other. Further, the nozzle 20 is positioned on the etched layer 110. The nozzle 20 moves from the seventh area 110g of the etched layer to the direction of the first area 110a of the etched layer.

In an embodiment, the first supply pipe 210 is positioned on the first area 110a of the etched layer, and the first suction pipe 215 is positioned on the second area 110b of the etched layer. The second supply pipe 220 is positioned on the third area 110c of the etched layer, and the second suction pipe 225 is positioned on the second suction pipe 225. In the same manner, the fourth supply pipe 240 is positioned on the seventh area 110g of the etched layer.

The first supply pipe 210 supplies the first etching solution 120a to the first area 110a of the etched layer, and the first suction pipe 215 sucks the second etching solution 120b that is in the second area 110b of the etched layer. The second etching solution 120b that is sucked by the first suction pipe 215 is the etching solution 120 that is supplied to the second area 110b of the etched layer before the first supply pipe 210 moves to the first area 110a of the etched layer. Except for the material of the etched layer 110, the first etching solution 120a and the second etching solution 120b may be substantially the same etching solution 120.

The second supply pipe 220 supplies the (1-1)-th cleaning solution 130a to the third area 110c of the etched layer, and the second suction pipe 225 sucks the (1-2)-th cleaning solution 130b that is in the fourth area 110d of the etched layer. The (1-2)-the cleaning solution 130b is the first cleaning solution 130 that is supplied to the fourth area 110d of the etched layer before the second supply pipe 220 moves to the third area 110c of the etched layer. The (1-1)-th cleaning solution 130a may be the first cleaning solution 130 that is substantially the same as the (1-2)-th cleaning solution 130b.

The third supply pipe 230 supplies the (2-1)-th cleaning solution 140a to the fifth area 110e of the etched layer, and the third suction pipe 235 sucks the (2-2)-th cleaning solution 140b that is in the sixth area 110f of the etched layer. The (2-2)-the cleaning solution 140b is the second cleaning solution 140 that is supplied to the sixth area 110f of the etched layer before the third supply pipe 230 moves to the fifth area 110e of the etched layer. The (2-1)-th cleaning solution 140a may be the cleaning solution 140 that is substantially the same as the (2-2)-th cleaning solution 140b.

Further, the fourth supply pipe supplies a drying gas to the seventh area 110g of the etched layer.

In the first to seventh areas 110a, 110b, 110c, 110d, 110e, 110f, and 110g of the etched layer that are successively adjacent to each other, the supplying of the first etching solution 120a, the (1-1)-th cleaning solution 130a, and the (2-1)-th cleaning solution 140a and the sucking of the second etching solution 120b, the (1-2)-th cleaning solution 130b, and the (2-2)-th cleaning solution 140b are simultaneously performed.

Since the etched amount of the first area 110a of the etched layer to be etched is determined, a relative speed v between the nozzle 20 and the substrate holder 10 is adjusted according to the etched amount of the first area 110a of the etched layer.

If the etched amount of the first area 110a of the etched layer is large, it is required to deeply etch the first area 110a of the etched layer, and thus the nozzle 20 moves slowly. Through this, the time required to etch the first area 110a of the etched layer is increased.

If the etched amount of the first area 110a of the etched layer is small, it is required to shallowly etch the first area 110a of the etched layer, and thus the nozzle 20 moves fast. Through this, the time required to etch the first area 110a of the etched layer is decreased.

It is assumed that the relative speed v between the nozzle 20 and the substrate holder 10 is constant. In this case, since the etched amount of the first area 110a of the etched layer to be etched is determined, the concentration of the first etching solution 120a that is supplied by the first supply pipe 210 is adjusted according to the etched amount of the first area 110a of the etched layer.

If the etched amount of the first area 110a of the etched layer is large, it is required to deeply etch the first area 110a of the etched layer, and thus the concentration of the first etching solution 120a is heightened. Through this, the etch rate of the first area 110a of the etched layer is increased.

If the etched amount of the first area 110a of the etched layer is small, it is required to shallowly etch the first area 110a of the etched layer, and thus the concentration of the first etching solution 120a is lowered. Through this, the etch rate of the first area 110a of the etched layer is decreased.

The first detector 250 senses an optical signal from the substrate 100 that is on the lower portion of the first detector 250. Using the optical signal sensed as described above, the controller 50 determines whether the substrate 100 is positioned on the lower portion of the first detector 250.

If the substrate 100 is not positioned on the lower portion of the first detector 250, the supply of the first etching solution 120a from the first supply pipe 210 is interrupted.

In an embodiment, the first detector 250 may be used to measure the thickness of the seventh area 110g of the etched layer of which the etching process is completed. The actual etch thickness of the seventh area 110g of the etched layer that is measured using the first detector 250 is compared with the etched amount of the seventh area 110g of the etched layer that is determined in S10.

If the actual etch thickness of the seventh area 110g of the etched layer is substantially equal to the etched amount of the seventh area 110g of the etched layer that is determined in S10, the local wet etching of the etched layer 110 is continuously performed through the nozzle 20.

However, if there is a great difference between the actual etch thickness of the seventh area 110g of the etched layer and the etched amount of the seventh area 110g of the etched layer that is determined in S10, it is required to correct the relative speed v between the nozzle 20 and the substrate holder 10 and the concentration of the first etching solution 120a. This is because the relative speed v between the nozzle 20 and the substrate holder 10 and the concentration of the first etching solution 120a are values that are calculated on the basis of the etched amount of the etched layer that is determined in S10.

For example, if the actual etch thickness of the seventh area 110g of the etched layer is larger than the etched amount of the seventh area 110g of the etched layer that is determined in S10, it is required to perform correction to heighten the relative speed v between the nozzle 20 and the substrate holder 10 or to lower the concentration of the first etching solution 120a.

Using FIGS. 13 and 14, the supply and suction of the solutions when the local wet etching is performed in a predetermined area will be described. For example, the seventh area 110g of the etched layer of FIG. 13 is referred to.

First, the first supply pipe 210 supplies the etching solution 120 to the seventh area 110g of the etched layer. The seventh area 110g of the etched layer is etched by the etching solution 120. Thereafter, the first suction pipe 215 sucks the etching solution 120 that remains on the seventh area 110g of the etched layer. Then, the second supply pipe 220 supplies the first cleaning solution 130 to the seventh area 110g of the etched layer. Then, the third supply pipe 230 supplies the second cleaning solution 140 to the seventh area 110g of the etched layer. Thereafter, the third suction pipe 235 sucks the second cleaning solution 140 that remains on the seventh area 110g of the etched layer. Then, the fourth supply pipe 240 supplies the drying gas to the seventh area 110g of the etched layer to dry the seventh area 110g of the etched layer.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A wet etching nozzle comprising:
a first supply pipe configured to supply a first solution to a substrate including an etched layer, the first solution for etching a partial area of the etched layer;
a first suction pipe configured to suck the first solution from the substrate;
a second supply pipe configured to supply a second solution for cleaning the partial area of the etched layer; and
a second suction pipe configured to suck the second solution from the substrate.

2. The wet etching nozzle of claim 1, further comprising:
a third supply pipe configured to supply a third solution for cleaning the etched layer;
a third suction pipe configured to suck the third solution from the substrate; and
a fourth supply pipe configured to supply a gas for drying the etched layer.

3. The wet etching nozzle of claim 1, wherein the first supply pipe, the first suction pipe, the second supply pipe, and the second suction pipe are in the form of circles, respectively, and
the first supply pipe, the first suction pipe, the second supply pipe, and the second suction pipe are arranged in the form of concentric circles.

4. The wet etching nozzle of claim 3, wherein the first supply pipe, the first suction pipe, the second supply pipe, and the second suction pipe are successively arranged in a radial direction.

5. The wet etching nozzle of claim 1, wherein the first supply pipe, the first suction pipe, the second supply pipe, and the second suction pipe are successively arranged in one direction.

6. The wet etching nozzle of claim 5, further comprising:
a third suction pipe arranged to correspond to the first suction pipe around the first supply pipe to suck the first solution;
a third supply pipe arranged to correspond to the second supply pipe around the first supply pipe to supply the second solution; and
a fourth suction pipe arranged to correspond to the second suction pipe around the first supply pipe to suck the second solution.

7. The wet etching nozzle of claim 1, further comprising:
a detector configured to detect an optical signal from the substrate,
wherein the detector includes a light source configured to irradiate the substrate with a first light and a sensor configured to sense a second light that is produced through reflection of the first light from the substrate.

8. The wet etching nozzle of claim 7, wherein the first supply pipe, the second supply pipe, and the detector are successively arranged in one direction.

9. The wet etching nozzle of claim 7, wherein the detector is arranged on both sides around the first supply pipe.

10. A wet etching nozzle comprising:
a first supply pipe configured to supply an etching solution to a part of a substrate including an etched layer;
a first suction pipe configured to suck the etching solution from the substrate; and
a detector including a light source configured to irradiate the substrate with a first light and a sensor configured to sense a second light that is produced through reflection of the first light from the substrate.

11. The wet etching nozzle of claim 10, further comprising:
a second supply pipe configured to supply a cleaning solution to the substrate;
a second suction pipe configured to suck the cleaning solution from the substrate; and
a third supply pipe configured to supply a drying gas to the substrate.

12. Semiconductor manufacturing equipment comprising:
a substrate holder on which a substrate including an etched layer is positioned;
a nozzle arranged on the substrate holder and including a first supply pipe configured to supply a first solution for etching the etched layer, a first suction pipe configured to suck the first solution from the substrate, a second supply pipe configured to supply a second solution for cleaning the etched layer, and a second suction pipe configured to suck the second solution from the substrate; and
a controller operationally connected to the nozzle and/or the substrate holder, the controller configured to adjust an etched amount of the etched layer.

13. The semiconductor manufacturing equipment of claim 12, wherein the nozzle further comprises:
a third supply pipe configured to supply a third solution for cleaning the substrate,
a third suction pipe configured to suck the third solution from the substrate, and
a fourth supply pipe configured to supply a gas for drying the substrate.

14. The semiconductor manufacturing equipment of claim 12, further comprising:
a detector connected to the controller and configured to detect an optical signal from the substrate.

15. The semiconductor manufacturing equipment of claim 14, wherein the controller is configured to determine whether the substrate is positioned on a lower portion of the detector using the optical signal.

16. The semiconductor manufacturing equipment of claim 14, wherein the controller is configured to measure a thickness of the etched layer using the optical signal.

17. The semiconductor manufacturing equipment of claim 12, wherein the controller is configured to change a relative speed between the nozzle and the substrate holder according to a thickness of the etched layer that is positioned on a lower portion of the first supply pipe.

18. The semiconductor manufacturing equipment of claim 12, wherein the controller is configured to change a concentration of the first solution according to a thickness of the etched layer that is positioned on a lower portion of the first supply pipe.

19. The semiconductor manufacturing equipment of claim 12, wherein the first supply pipe, the first suction pipe, the second supply pipe, and the second suction pipe are in the form of circles, and
the first supply pipe, the first suction pipe, the second supply pipe, and the second suction pipe are arranged in the form of concentric circles.

20. The semiconductor manufacturing equipment of claim 12, wherein the first supply pipe, the first suction pipe, the second supply pipe, and the second suction pipe are successively arranged in one direction.
